(19) United States
(12) Patent Application Publication
(10) Pub. No.: US 2004/0241554 A1
(43) Pub. Date: Dec. 2, 2004

(54) Ion implantation phase shift mask

(75) Inventors: Paul Rissman, Palo Alto, CA (US); Nicholas K. Eib, San Jose, CA (US); Charles E. May, Gresham, OR (US)

Correspondence Address: LSI LOGIC CORPORATION, Intellectual Property Department, 1551 McCarthy Boulevard, MS D-106, Milpitas, CA, 95035, US

(73) Assignee: LSI Logic Corporation, Milpitas, CA

(21) Appl. No.: 10/447,381

(22) Filed: May 29, 2003

(51) Int. Cl. H01L 21/76; G03F 9/00; C03C 15/00; B44C 1/22; C23F 1/00; C03C 25/68

(52) U.S. Cl. 430/5; 216/66

(57) ABSTRACT

The mask includes a substrate formed of a material having a first index of refraction and a first level of transmittance to a wavelength of light with which the phase shift mask is designed for use. Second portions of the substrate are impregnated with a dopant species, leaving first portions of the substrate unaffected by the dopant species. The second portions of the substrate have a second index of refraction and a second level of transmittance to the wavelength of light. The first index of refraction is not equal to the second index of refraction. The second portions of the substrate shift a phase of the light relative to the first portions of the substrate and thereby increase an effective imaging resolution of the phase shift mask. In this manner, instead of using an etch process or a deposition process to form phase shifting regions of the mask, a doping processing is used instead. Most preferably, an ion implantation process is used. As ion implantation tends to be extremely well behaved and controllable, the mask according to the present invention has phase shifting regions that can be formed with a high degree of control and uniformity across the mask substrate.

### FIELD

This invention relates to the field of integrated circuit fabrication. More particularly, this invention relates to the fabrication of phase shift masks.

### BACKGROUND

As integrated circuits continue to shrink in size, the processes by which they are formed are increasingly limited by fundamental physical laws. For example, in forming structures, such as gate structures in a metal oxide semiconductor device, that are less than about a quarter micron in length, or in other words less than about 250 nanometers long, the ability of the radiation used to pattern the structure during the photo lithographic process is seriously challenged. Typical deep sub micron photo lithography processes use deep ultra violet radiation with a wavelength of about 248 nanometers to expose the photo resist used to pattern the structures. Unfortunately, a beam of light with a wavelength of 248 nanometers has difficulty in resolving the closely spaced features in a masking pattern that is not appreciably greater than the wavelength of the light. Thus, the processes used to form integrated circuits must necessarily change as even smaller device features, such as 100 nanometers gate lengths, are desired.

One method of forming devices with smaller features is to use electromagnetic radiation with smaller wavelengths during the photo lithography process. For example, electromagnetic radiation with a wavelength of 193 nanometers provides the ability to pattern features that are about twenty percent smaller than those patterned with electromagnetic radiation having a wavelength of 248 nanometers. However, moving to steppers and other exposure tools that utilize 193 nanometers technology is still insufficient, of itself, to produce 100 nanometers features. Radiation with even shorter wavelengths, such as 157 nanometers, presents serious cost considerations and other technical challenges. Thus, other improvements to the photo lithography process are required.

Some of these other improvements provide for the ability to accomplish so-called sub wavelength patterning of photo resist. By this it is meant that the techniques employed provide the ability for the electromagnetic radiation to pattern features that have dimensions that are smaller than the wavelength of the electromagnetic radiation so employed. One such technique is the use of phase shift masks.

A phase shift mask makes use of the interference that is produced between waves of electromagnetic radiation that are out of phase one with another. By use of this interference property, very small feature sizes can be patterned. There are two general categories of phase shift masks, being alternating or Levees phase shift masks, and partially transmitting or attenuating phase shift masks.

The phase shift of an alternating phase shift mask is typically created by etching recesses in the mask substrate, which is commonly formed of quartz, in the following manner. An opaque layer, such as of chrome, is first formed and patterned over the quartz substrate, and then a second photo resist pattern is formed, and a portion of the substrate that is exposed through some of the openings in the opaque layer is etched to a desired depth using a plasma etch process. The depth of the etch into the substrate must be highly controlled to produce a phase offset or shift of 180 degrees with the unwatched portions of the substrate. For 248 nanometers lithography, the desired etch depth is about 240 nanometers, and for 193 nanometers lithography, the desired etch depth is about 190 nanometers.

If the depth of the etched portions of the substrate is not precisely controlled, then the phase shift is not close enough to 180 degrees to produce the desire interference patterns and provide the desired resolution. A phase error of only about ten percent can cause a line width error in the integrated circuit of as much as about twenty percent. The resulting mask phase errors cause images to shift through focus.

However, etch uniformity across the mask substrate is difficult to achieve. Relatively smaller openings in the substrate tend to etch at a slower effective rate than larger openings. As the larger openings are typically used for in-process monitoring of the depth of etch, the smaller openings may often be etched to an improper depth. Loss of uniformity from problems such as these can render a mask unusable. In addition, a very precise sidewall, or in other words, a very vertical sidewall is desirable for the etched portions. This characteristic is also difficult to produce with tight uniformity across the mask substrate.

Attenuating phase shift masks are formed by an alternate process, where the mask substrate is coated with a thin layer of an absorber/shifter material, such as molybdenum silicate for 248 nanometers lithography. The material partially absorbs the light and creates a 180 degree phase shift. Patterned portions of the material are removed from the substrate. Light is reduced in intensity and phase shifted by the coated portions of the mask substrate, which sharpens the edges of the exposed regions, and thereby improves the imaging process. However, attenuating phase shift masks require a relatively high degree of control of the deposition process by which the absorbing/shifting material is formed, or the mask will not function properly.

What is needed, therefore, is a system for creating a phase shift mask in a way by which they can be very finely tuned for optical performance.

### SUMMARY

The above and other needs are met by a phase shift mask according to a preferred embodiment of the present invention. The mask includes a substrate formed of a material having a first index of refraction and a first level of transmittance to a wavelength of light with which the phase shift mask is designed for use. Second portions of the substrate are impregnated with a dopant species, leaving first portions of the substrate unaffected by the dopant species. The second portions of the substrate have a second index of refraction and a second level of transmittance to the wavelength of light. The first index of refraction is not equal to the second index of refraction. The second portions of the substrate shift a phase of the light relative to the first portions of the substrate and thereby increase an effective imaging resolution of the phase shift mask.

In this manner, instead of using an etch process or a deposition process to form phase shifting regions of the mask, a doping process is used instead. Most preferably, an ion implantation process is used. As ion implantation tends to be extremely well behaved and controllable, the phase shift mask according to the present invention has phase shifting regions that can be formed with a high degree of control and uniformity across the mask substrate.

In various preferred embodiments, an opaque layer overlies parts of the first portions of the substrate, thus forming an alternating phase shift mask. Most preferably, the opaque layer is a chrome layer. The substrate is preferably formed of quartz. Preferably, the second index of refraction in the damaged area of the substrate is greater than the first index of refraction in the undamaged area of the substrate. In one embodiment the second level of transmittance in the damaged area of the substrate is less than the first level of transmittance in the undamaged area of the substrate, thus forming an attenuated phase shift mask. The dopant species is preferably at least one of nitrogen, an inert gas, and a metal. The phase shift between the first portions of the substrate and the second portions of the substrate is preferably about one hundred and eighty degrees.

According to another aspect of the invention there is described a phase shift mask including a substrate formed of a material having a first index of refraction and a first level of transmittance to a wavelength of light with which the phase shift mask is designed for use. An opaque layer overlies the substrate, where the opaque layer has apertures through which first portions and second portions of the substrate are exposed. The second exposed portions of the substrate are impregnated with a dopant species, leaving the first exposed portions of the substrate unaffected by the dopant species. The second portions have a second index of refraction and an identical level of transmittance to the wavelength of light. The first index of refraction is not equal to the second index of refraction. The second portions shift a phase of the light relative to the first portions and thereby increase an effective imaging resolution of the phase shift mask, which functions like an alternating phase shift mask.

According to yet another aspect of the invention there is described a phase shift mask having a substrate formed of a material having a first index of refraction and a first level of transmittance to a wavelength of light with which the phase shift mask is designed for use. The substrate has no opaque layers formed thereon. Second portions of the substrate are impregnated with a dopant species, leaving first portions of the substrate unaffected by the dopant species. The second portions of the substrate have a second index of refraction and a second level of transmittance to the wavelength of light. The first index of refraction is not equal to the second index of refraction, and the second level of transmittance is less than the first level of transmittance. The second portions of the substrate shift a phase of the light relative to the first portions of the substrate and thereby increase an effective imaging resolution of the phase shift mask, which functions like an attenuated phase shift mask.

According to a further aspect of the invention there is described a method of forming a phase shift mask, by forming a layer of an opaque material on a surface of a substrate. The substrate has a first index of refraction to a wavelength of light with which the phase shift mask is designed for use. The layer of the opaque material is patterned to expose first portions and second portions of the surface of the substrate, and a masking layer is formed over at least the first exposed portions of the surface of the substrate. The substrate is impregnated through the second exposed portions of the surface of the substrate with a dopant species, where the dopant species is impregnated to a depth within the substrate. The second portions of the substrate thereby have a second index of refraction. The masking layer is removed from the substrate.

According to still a further aspect of the invention there is described a method of forming a phase shift mask in a substrate having a first index of refraction and a first transmittance to a wavelength of light with which the phase shift mask is designed for use. A masking layer is formed over first portions of the surface of the substrate, and the substrate is impregnated through second exposed portions of the surface of the substrate with a dopant species. The dopant species is impregnated to a depth within the substrate, thereby causing the second portions of the substrate to have a second index of refraction and a second transmittance to the wavelength of light with which the phase shift mask is designed for use. The second transmittance is less than the first transmittance and the first index of refraction is less than the second index of refraction. The masking layer is removed from the substrate.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross sectional diagram of a phase shift mask according to the present invention, depicting a substrate, opaque layer, and etch mask,

FIG. 2 is a cross sectional diagram of the phase shift mask of FIG. 1, depicting first and second openings in the etch mask,

FIG. 3 is a cross sectional diagram of the phase shift mask of FIG. 2, depicting first and second openings in the opaque layer, and a newly patterned mask layer,

FIG. 4 is a cross sectional diagram of the phase shift mask of FIG. 3, depicting a dopant impregnated through the opening in the mask layer and into the substrate,

FIG. 5 is a cross sectional diagram of the phase shift mask of FIG. 4, depicting an impregnated portion of the substrate,

FIG. 6 is a cross sectional diagram of the phase shift mask of FIG. 5, depicting the phase shift mask with the mask layer removed, and

FIG. 7 is a cross sectional diagram of a phase shift mask according to the present invention, depicting a substrate with an impregnated portion and no opaque layers on the substrate.

### DETAILED DESCRIPTION

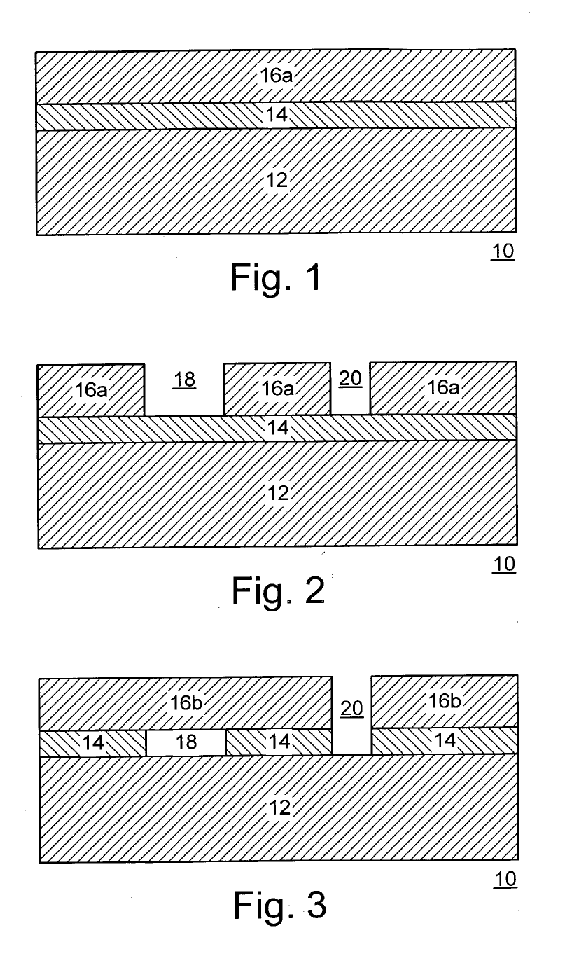

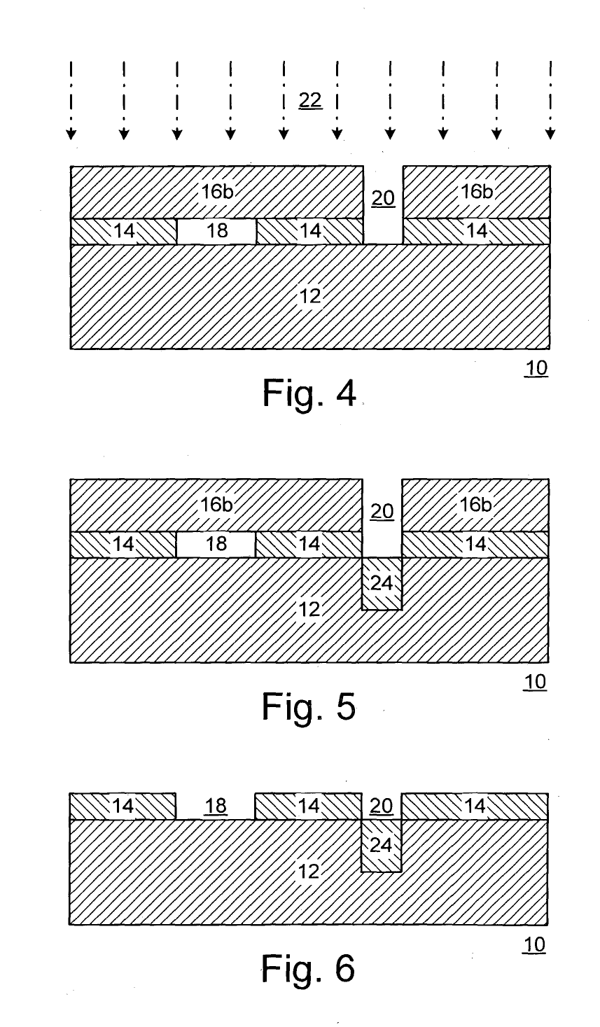

With reference now to FIG. 1 there is depicted a cross sectional diagram of a phase shift mask 10 according to the present invention, depicting a substrate 12, opaque layer 14, and etch mask 16a. The mask substrate 12 is preferably formed of an optically transparent material such as sapphire, or most preferably quartz. The opaque layer 14 is preferably a metal layer, such as chrome. The etch mask 16a is preferably a photo resist that can be either optically patterned or electron patterned.

As depicted in FIG. 2, the etch mask 16a is preferably patterned to create two open portions 18 and 20, defining regions 18 and 20 in the substrate 12. The opaque layer 14 is preferably etched through the open portions 18 and 20, which exposes first and second portions of the surface of the substrate 12 as depicted in FIG. 3. The etch is preferably either a wet chemistry etch or a plasma etch, which is selective between the materials of the opaque layer 14 and the substrate 12.

FIG. 3 also depicts a second masking layer 16b that has been applied over the opaque layer 14. However, as depicted in FIG. 3, there is only an opening formed in the masking layer 16b over the exposed surface of the second portion 20 of the substrate 12, while the first portion 18 has been covered with the masking layer 16b.

A dopant species 22 is preferably impregnated into the exposed second portion 20 of the substrate 12, most preferably such as by ion implantation. The dopant species is preferably at least one of a metal or an inert gas, such as nitrogen. The masking layer 16b protects all of the covered first portions 18 of the substrate 12 and the opaque layer 14. In this manner, only the second portion 20 of the substrate 12 is exposed to the ion implantation of the species 22. The depth of the damaged area 24 can be controlled by the acceleration voltage used during the impregnation process. This formula is empirically derived, but the depth for a nitrogen dopant species 22 in a quartz substrate 12 is preferably equal to the voltage times 3.29 plus 11.45.

As depicted in FIG. 5, the impregnation of the dopant species into the second exposed portion 20 of the substrate 12 forms a damaged region 24 in the second portion 20 of the substrate 12. The degree of damage can be controlled to a relatively high degree, such as by selecting dopant species 20 of heavier or lighter atomic weight, or selectively increasing or decreasing the dopant level of the species. The depth of the damaged region 24 can also be relatively precisely controlled, such as by selectively increasing and decreasing the energy used to implant the dopant species into the substrate 12. Thus, the degree of damage and the depth of the damaged region 24 is highly controllable, and is extremely uniform in all of the exposed second portions 20 across the surface of the phase shift mask 10.

Following the impregnation of the dopant species 22, the masking layer 16b is preferably stripped from the surface of the phase shift mask 10, at which point the fabrication of the phase shift mask 10 is preferably complete. The remaining opaque layer 14 blocks light from passing through the phase shift mask 10 in those areas where it remains. The light passing through the undamaged first portions 18 of the phase shift mask 10 will experience a baseline phase shift as it passes through the substrate 12.

However, the light passing through the second portions 20 of the phase shift mask 10 will experience a different degree of phase shifting as it passes through the damaged regions 24 and then through a different thickness of underlying undamaged substrate 12.

The relative phase shift in the light passing through the first portion 18 and the second portion 20 can be controlled by factors such as the dopant species 22, the degree of damage in the damaged region 24 and the depth of the damaged region 24, all of which can be precisely controlled. Thus, the shifter region 20 of the phase shift mask 10 can be formed with a high degree of control, which overcomes many of the problems described above. Most preferably, the damaged region 24 is formed so as to produce a phase shift through the second region 20 of about one hundred and eighty degrees, relative to the first portion 18. In this manner, different extinction patterns can be generated, improving the apparent resolution produced by the phase shift mask 10, which functions in a manner similar to an alternating phase shift mask, as described above.

However, in alternate embodiments, phase shifts of sixty degrees, one hundred and twenty degrees, and one hundred and eighty degrees can be achieved in steps to form specialized masks, such as those described in U.S. Pat. No. 5,573,890 to Spencer, the disclosure of which is included herein by reference.

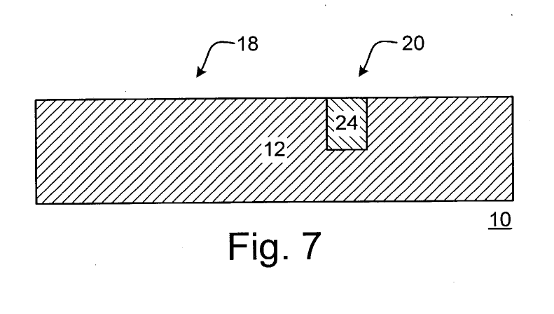

The phase shift mask 10 may be alternately formed as depicted in FIG. 7, without any opaque layers. In this embodiment, the etch mask 16a and subsequent etch thereof is omitted, and processing starts with the application and patterning of the masking layer 16b. As mentioned, the substrate 12 of this embodiment does not have any opaque layer 14 on it at any time. In this embodiment, damaged regions 24 are created in second portions 20 of the mask 10 to form extinction patterns as desired, which operate in much the same way as does a attenuated phase shift mask, as described above.

In this embodiment, the impregnated dopant species 22 preferably not only forms a damaged region 24 that has a different index of refraction from the undamaged first portions 18, but also preferably has a different transmittance of the wavelength of the light that is intended to be used with the phase shift mask 10. In this embodiment, the phase shift through the second portion 20 of the mask 10 is preferably about one hundred and eighty degrees relative to the first regions 18, and the damaged area 24 preferably has a reduced transmittance in relation to the first portions 18, thus attenuating the light that passes through the second portions 20. In this embodiment, the impregnated species 22 may be a metal species.

Because the implantation process is highly controllable, the uniformity and precision with which the mask 10 can be fabricated is also highly controllable, thus yielding extremely precise phase shift masks 10. The depth of the damaged area 24 required to create a phase shift of 180 degrees is equal to the wavelength of light to be used with the mask divided by twice the difference between index of refraction of the substrate 10 and the index of refraction of the damaged area 24.

Thus, the index of refraction for a damaged portion 24, using a given implanted species, can be determined for a give wavelength of light, by forming and testing a sample damaged portion 24 in a test substrate. Then the difference between the index of refraction for the damaged portion 24 and the desired substrate material 12 in an undamaged portion 18 can be determined, and used to yield a desired depth for the damaged portion 24, which will yield, for example, a 180 degree shift. The desired depth can then be used to determine the acceleration voltage needed to form the damaged region 24 to the desired depth. The phase shift mask 10 can then be fabricated according to the methods described above, either with or without an opaque layer 14, depending on the type of phase shift mask desired.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as is suited to the particular use contemplated. All such modifications and variations are within the scope of the invention as determined by the appended claims when interpreted in accordance with the breadth to which they are fairly, legally, and equitably entitled.

1. A phase shift mask, comprising:
a substrate having planar upper and lower surfaces, the substrate formed of a material having a first index of refraction and a first level of transmittance to a wavelength of light with which the phase shift mask is designed for use,
second portions of the substrate impregnated with a dopant species, leaving first portions of the substrate unaffected by the dopant species, the second portions of the substrate having a second index of refraction and a second level of transmittance to the wavelength of light, the fist index of refraction is not equal to the second index of refraction, and the second portions of the substrate shift a phase of the light relative to the first portions of the substrate and thereby increase an effective imaging resolution of the phase shift mask, and
an opaque layer rising above the planar upper surface of the substrate, and overlying parts of the first and second portions of the substrate.

2. (Cancelled).

3. The phase shift mask of claim 1, wherein the opaque layer is a chrome layer.

4. The phase shift mask of claim 1, wherein the substrate is formed of quartz.

5. The phase shift mask of claim 1, wherein the second index of refraction is greater than the first index of refraction.

6. The phase shift mask of claim 1, wherein the second level of transmittance is less than the first level of transmittance.

7. The phase shift mask of claim 1, wherein the dopant species is nitrogen.

8. The phase shift mask of claim 1, wherein the dopant species is a metal.
